(19) United States
(12) Patent Application Publication
(10) Pub. No.: US 2025/0183174 A1
(43) Pub. Date: Jun. 5, 2025

(54) ELECTRONIC DEVICE HAVING A BRASABLE METAL PAD COVER AND ASSOCIATED METHOD

(71) Applicant: STMicroelectronics International N.V., Geneva (CH)

(72) Inventors: Michele MOLGG, Agrate Brianza (MB) (IT); Mooi Kun TEOH, Singapore (SG); Maurizio Gabriele CASTORINA, Singapore (SG)

(21) Appl. No.: 18/526,447

(22) Filed: Dec. 1, 2023

(51) Int. Cl. H01L 23/532; H01L 21/768

(52) U.S. Cl. CPC H01L 23/53223; H01L 21/76874

(57) ABSTRACT

In accordance with various embodiments of the present disclosure, an electronic device is provided. In some embodiments, the electronic device comprises a semiconductor substrate, an aluminum pad on the semiconductor substrate, and a stack. The stack comprises, in sequence, a barrier layer directly deposited on the aluminum pad, a seed layer directly deposited on the barrier layer, the seed layer comprising copper and having a thickness less than 800 nanometers, and a metal layer directly deposited on the seed layer, the metal layer comprising nickel and palladium.

### FIELD OF THE INVENTION

Example embodiments of the present disclosure relate generally to integrated circuit fabrications and, more particularly, to brasable metal layers on aluminum pads of integrated circuits.

### BACKGROUND

In the field of power devices (e.g., silicon carbide (SiC) technology), there is need to cover the aluminum pad of such devices with a brasable (or wettable) metal. A brasable metal is a metal able to be uniformly covered by a solder paste. This allows a stable attachment of the clips used in packaging to the aluminum pad.

Applicant has identified many technical challenges and difficulties associated with providing such a brasable metal layer to cover an aluminum pad of an electronic device. Through applied effort, ingenuity, and innovation, Applicant has solved problems related to providing a brasable metal layer to cover an aluminum pad of an electronic device by developing solutions embodied in the present disclosure, which are described in detail below.

### BRIEF SUMMARY

Various embodiments described herein related to electronic devices, integrated circuits, and methods for providing a brasable metal layer to cover an aluminum pad of an electronic device.

In accordance with various embodiments of the present disclosure, an electronic device is provided. In some embodiments, the electronic device comprises a semiconductor substrate, an aluminum pad on the semiconductor substrate, and a stack. The stack comprises, in sequence, a barrier layer directly deposited on the aluminum pad, a seed layer directly deposited on the barrier layer, the seed layer comprising copper and having a thickness less than 800 nanometers (nm), and a metal layer directly deposited on the seed layer, the metal layer comprising nickel and palladium.

In some embodiments, the metal layer comprises a first metal sub-layer comprising nickel directly deposited on the seed layer and a second metal sub-layer comprising palladium directly deposited on the first metal sub-layer.

In some embodiments, the first metal sub-layer entirely covers a top surface of the seed layer.

In some embodiments, the seed layer has a thickness of 250-600 nm.

In some embodiments, the metal layer has a thickness greater than 500 nm.

In some embodiments, a sectional view of the seed layer has a substantially constant width from the barrier layer to the metal layer.

In some embodiments, the seed layer consists of a single layer of copper.

In some embodiments, the barrier layer comprises titanium, titanium-nitride, titanium-tungsten, tantalum, and/or tantalum-nitride.

In some embodiments, the barrier layer consists of a layer made of titanium, titanium-nitride, titanium-tungsten, tantalum, and/or tantalum-nitride.

In some embodiments, the metal layer consists of the first and second metal sub-layers.

In accordance with various embodiments of the present disclosure, a method of manufacturing an electronic device is provided. In some embodiments, the method comprises providing an aluminum pad on a semiconductor substrate of the electronic device and forming a stack on the aluminum pad. The forming comprises depositing a barrier layer directly on the aluminum pad, depositing a seed layer directly on the barrier layer, the seed layer comprising copper and having a thickness less than 800 nanometers (nm), and depositing a metal layer directly on the seed layer, the metal layer comprising nickel and palladium.

The above summary is provided merely for purposes of summarizing some example embodiments to provide a basic understanding of some aspects of the disclosure. Accordingly, it will be appreciated that the above-described embodiments are merely examples and should not be construed to narrow the scope or spirit of the disclosure in any way. It will also be appreciated that the scope of the disclosure encompasses many potential embodiments in addition to those here summarized, some of which will be further described below.

### BRIEF DESCRIPTION OF THE DRAWINGS

The description of the illustrative embodiments may be read in conjunction with the accompanying figures. It will be appreciated that, for simplicity and clarity of illustration, elements illustrated in the figures have not necessarily been drawn to scale, unless described otherwise. For example, the dimensions of some of the elements may be exaggerated relative to other elements, unless described otherwise. Embodiments incorporating teachings of the present disclosure are shown and described with respect to the figures presented herein, in which:

FIG. 1 is a cross-sectional view of an example portion of an electronic device, in accordance with some embodiments of the present disclosure; and

FIG. 2 is a cross-sectional view of an example portion of an electronic device, in accordance with some alternative embodiments of the present disclosure.

### DETAILED DESCRIPTION OF THE INVENTION

Some embodiments of the present disclosure will now be described more fully hereinafter with reference to the accompanying drawings, in which some, but not all embodiments of the disclosure are shown. Indeed, these disclosures may be embodied in many different forms and should not be construed as limited to the embodiments set forth herein; rather, these embodiments are provided so that this disclosure will satisfy applicable legal requirements. Like numbers refer to like elements throughout.

As used herein, terms such as “front,” “rear,” “top,” etc. are used for explanatory purposes in the examples provided below to describe the relative position of certain components or portions of components. Furthermore, as would be evident to one of ordinary skill in the art in light of the present disclosure, the terms “substantially” and “approximately” indicate that the referenced element or associated description is accurate to within applicable engineering tolerances.

As used herein, the term “comprising” means including but not limited to and should be interpreted in the manner it is typically used in the patent context. Use of broader terms such as comprises, includes, and having should be understood to provide support for narrower terms such as consisting of, consisting essentially of, and comprised substantially of.

The phrases “in one embodiment,” “according to one embodiment,” and the like generally mean that the particular feature, structure, or characteristic following the phrase may be included in at least one embodiment of the present disclosure, and may be included in more than one embodiment of the present disclosure (importantly, such phrases do not necessarily refer to the same embodiment).

The word “example” or “exemplary” is used herein to mean “serving as an example, instance, or illustration.” Any implementation described herein as “exemplary” is not necessarily to be construed as preferred or advantageous over other implementations.

If the specification states a component or feature “may,” “can,” “could,” “should,” “would,” “preferably,” “possibly,” “typically,” “optionally,” “for example,” “often,” or “might” (or other such language) be included or have a characteristic, that a specific component or feature is not required to be included or to have the characteristic. Such a component or feature may be optionally included in some embodiments, or it may be excluded.

Various embodiments of the present disclosure overcome the above technical challenges and difficulties and provide various technical improvements and advantages based on, for example, but not limited to, providing nickel-palladium (Ni—Pd) as a brasable metal layer on an aluminum pad of an electronic device, which provides good coverage by the solder paste for attaching a clip to the aluminum pad.

Various embodiments of the present disclosure provide a layered stack (referred to herein as a stack) of different materials, for different purposes, applied to an aluminum pad of an electronic device. In various embodiments, a stack applied to an aluminum pad of an electronic device comprises, in sequence, a barrier layer directly deposited on the aluminum pad, a seed layer directly deposited on the barrier layer, and a metal layer directly deposited on the seed layer. In various embodiments, the seed layer comprises copper and the metal layer comprises nickel and palladium sub-layers.

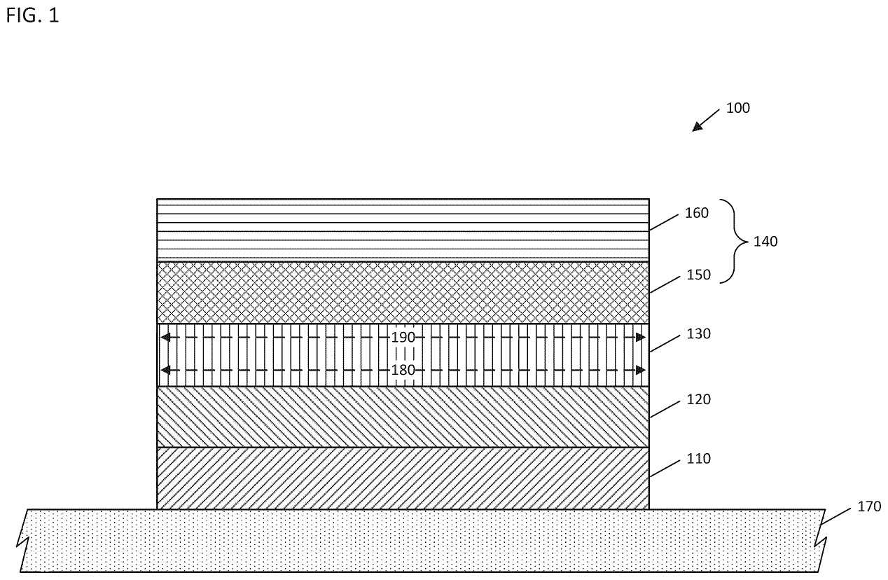

FIG. 1 illustrates a cross-sectional view of an example stack of an electronic device, in accordance with some embodiments of the present disclosure. As seen in FIG. 1, the electronic device comprises a semiconductor substrate 170 and an aluminum pad 110 placed thereon. For example, the aluminum pad has an area (in plan view) of 1000×1000 square micrometers (μm²). Aluminum pads of any area could be used, for example having an area of 420×560 μm2 or an area of 2040×1900 μm². The electronic device further comprises a stack 100 which exemplarily comprises a barrier layer 120 directly deposited on the aluminum pad 110, a seed layer 130 directly deposited on the barrier layer 120, and a metal layer 140 directly deposited on the seed layer 130. Exemplarily the stack 100 continuously and entirely covers the aluminum pad (in other words, the area—in plan view—of the stack is at least equal to the area—in plan view—of the aluminum pad). In some embodiments, the metal layer 140 comprises a first sub-layer of nickel 150 and a second sub-layer of palladium 160. In some embodiments, the seed layer 130 comprises a layer of copper. In some embodiments, the seed layer 130 comprises a single layer of copper. In some embodiments, the seed layer 130 comprises a layer of copper having a thickness less than 800 nanometers (nm). In some embodiments, the seed layer 130 comprises a layer of copper having a thickness of 250-600 nm, and in some embodiments a thickness of about 300-500 nm. In some embodiments, the barrier layer comprises titanium, titanium-nitride, titanium-tungsten, tantalum, and/or tantalum-nitride.

In some embodiments, the nickel sub-layer of the metal layer is directly deposited on the seed layer and the palladium sub-layer of the metal layer is directly deposited on the nickel sub-layer of the metal layer. In some embodiments, the metal layer has a thickness greater than (or equal to) 500 nm. In some embodiments, the nickel sub-layer is at least 500 nm, and the palladium sub-layer is at least 150 nm. In some embodiments, the metal layer is deposited via electroless deposition (also termed e-less deposition). In some embodiments, both the nickel and the palladium sub-layers are deposited via electroless deposition. Using electroless deposition enables the thickness of the nickel and palladium sub-layers to be modulated within a large range and with a greater thickness than with other deposition techniques.

The thickness of the nickel and palladium sub-layer is modulated as a function of the technological purpose. For example, as regards the nickel sub-layer, the thickness can vary in a range of 500-5000 nm, depending on the technological purpose (e.g., barrier function, mechanical buffer function, and/or chemical reaction function). In some embodiments, the nickel sub-layer should have a thickness able to withstand the nickel consumption (so that a certain thickness still remains in the final device) due to the wire bonding process (occurring in a later production phase) when the solder paste is positioned on the palladium. The palladium sub-layer for example has the function to protect the nickel sub-layer and to be wettable, therefore in some embodiments a range of 150-500 nm is used.

In some embodiments, using electroless deposition enables the nickel sub-layer to have a thickness in the abovesaid range of 500 nm to 5 micrometers. In various embodiments, the use of a nickel-palladium metal layer deposited by electroless deposition enables a greater total stack height as compared to other approaches that have been used, which may be desirable in some applications. In some embodiments, the barrier layer and the seed layer are deposited via physical vapor deposition. Alternatively, any suitable deposition method may be used for these layers.

In some embodiments, the width of the seed layer is substantially constant from the barrier layer to the metal layer. For the purposes of embodiments of the present disclosure, the expression “substantially constant” means that an actual width value of the seed layer varies, along a direction going from the barrier layer to the metal layer, within a range of +/−10% (and preferably of +/−5%) from a nominal width value. For example, the nominal width value is 1000 μm and the actual width value is between 900 μm and 1100 μm. This is illustrated in FIG. 1 by the substantially equal length dashed lines 180, 190 indicating the width of the seed layer 130, with the dashed line 180 indicating the width at a lower point of the seed layer 130 (i.e., closer to the barrier layer 120) and the dashed line 190 indicating the width at a higher point of the seed layer 130 (i.e., closer to the nickel sub-layer 150).

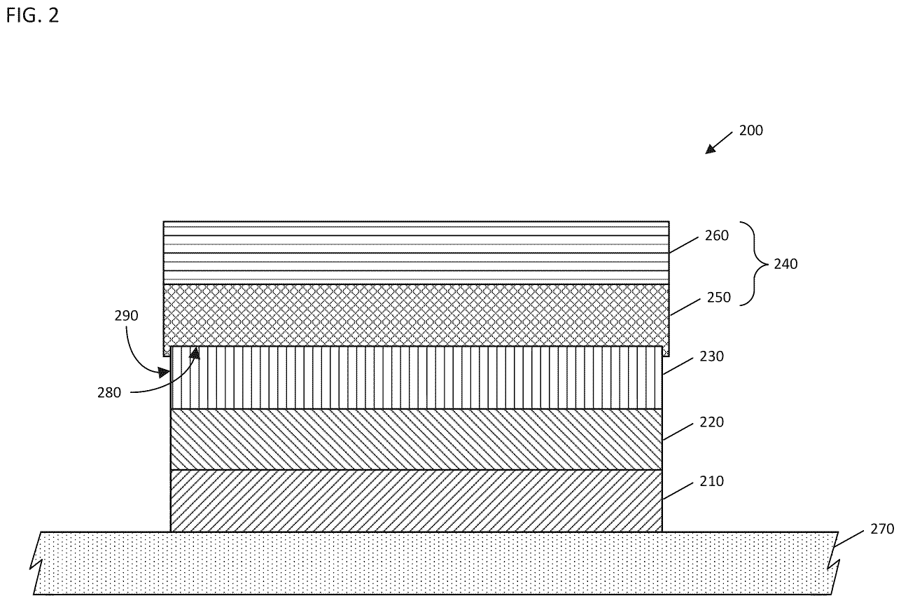

FIG. 2 illustrates a cross-sectional view of an example stack of an electronic device, in accordance with some embodiments of the present disclosure. As seen in FIG. 2, the electronic device comprises a semiconductor substrate 270 and an aluminum pad 210 placed thereon. The electronic device further comprises a stack 100 which exemplarily comprises a barrier layer 220 directly deposited on the aluminum pad 210, a seed layer 230 (such as copper) directly deposited on the barrier layer 220, and a metal layer 240 directly deposited on the seed layer 230. In some embodiments, the metal layer 240 comprises a first sub-layer of nickel 250 and a second sub-layer of palladium 260. In some embodiments, the sub-layer of nickel 250 of the metal layer 240 substantially covers a top surface 280 of the seed layer 230. In some embodiments, as illustrated, the electroless deposition of the sub-layer of nickel 250 causes a partial deposition of the nickel also on at least a portion of the sidewall 290 of the seed layer 230, thus completely covering the top surface 280 of the seed layer 230.

In various embodiments, the stack as described herein may provide a more uniform interface among the different layers and thereby avoid delayering, as compared to other approaches that have been used. Moreover, the presence of the barrier and seed layers between the aluminum pad and the nickel sub-layer allows to avoid the direct deposition of the nickel, for example through the e-less process, on the aluminum. In fact, Applicant has verified that the e-less chemistry for depositing the nickel on aluminum could cause a damaging of the pad that is difficult to predict. In embodiments of the present disclosure, the interposition of barrier and seed layers allows to obtain a more regular surface of the aluminum pad on one side, and, on the other, the deposition of the nickel on a surface (i.e., the seed layer) substantially insensitive to the action of the e-less chemistry, thus achieving an overall better interface.

Various embodiments of the disclosure may be used with any electronic device having an aluminum pad requiring a wettable/brasable metal, including but not limited to SiC devices as described herein, as well as gallium nitride or silicon devices (e.g., insulated-gate bipolar transistors (IGBT)).

### Conclusion

Many modifications and other embodiments of the disclosures set forth herein will come to mind to one skilled in the art to which these disclosures pertain having the benefit of teachings presented in the foregoing descriptions and the associated drawings. Although the figures only show certain components of the apparatus and systems described herein, it is understood that various other components may be used in conjunction with the system. Therefore, it is to be understood that the disclosures are not to be limited to the specific embodiments disclosed and that modifications and other embodiments are intended to be included within the scope of the appended claims. Moreover, the steps in the method described above may not necessarily occur in the order depicted in the accompanying diagrams, and in some cases one or more of the steps depicted may occur substantially simultaneously, or additional steps may be involved. Although specific terms are employed herein, they are used in a generic and descriptive sense only and not for purposes of limitation.

While various embodiments in accordance with the principles disclosed herein have been shown and described above, modifications thereof may be made by one skilled in the art without departing from the spirit and the teachings of the disclosure. The embodiments described herein are representative only and are not intended to be limiting. Many variations, combinations, and modifications are possible and are within the scope of the disclosure. The disclosed embodiments relate primarily to fragmented wideband tympanometry techniques for true wireless stereo, however, one skilled in the art may recognize that such principles may be applied to any audio device. Alternative embodiments that result from combining, integrating, and/or omitting features of the embodiment(s) are also within the scope of the disclosure. Accordingly, the scope of protection is not limited by the description set out above.

Additionally, the section headings used herein are provided for consistency with the suggestions under 37 C.F.R. 1.77 or to otherwise provide organizational cues. These headings shall not limit or characterize the disclosure(s) set out in any claims that may issue from this disclosure.

While this detailed description has set forth some embodiments of the present disclosure, the appended claims cover other embodiments of the present disclosure which differ from the described embodiments according to various modifications and improvements. For example, the appended claims can cover any form of electronic device which has one or more aluminum pads, such as but not limited to silicon and/or silicon carbide (SiC) power devices. Non-limiting examples of power devices are metal-oxide-semiconductor field-effect transistors (MOSFETs), insulated-gate bipolar transistors (IGBT), and Schottky barrier diodes.

Within the appended claims, unless the specific term “means for” or “step for” is used within a given claim, it is not intended that the claim be interpreted under 35 U.S.C. 112, paragraph 6.

What is claimed is:

1. An electronic device comprising:
a semiconductor substrate;
an aluminum pad on the semiconductor substrate; and
a stack comprising, in sequence:
a barrier layer directly deposited on the aluminum pad;
a seed layer directly deposited on the barrier layer, the seed layer comprising copper and having a thickness less than 800 nanometers (nm); and
a metal layer directly deposited on the seed layer, the metal layer comprising nickel and palladium.

2. The electronic device of claim 1, wherein the metal layer comprises a first metal sub-layer comprising nickel directly deposited on the seed layer and a second metal sub-layer comprising palladium directly deposited on the first metal sub-layer.

3. The electronic device of claim 2, wherein the first metal sub-layer entirely covers a top surface of the seed layer.

4. The electronic device of claim 2, wherein the metal layer consists of the first and second metal sub-layers.

5. The electronic device of claim 1, wherein the seed layer has a thickness of 250-600 nm.

6. The electronic device of claim 1, wherein the metal layer has a thickness greater than 500 nm.

7. The electronic device of claim 1, wherein a sectional view of the seed layer has a substantially constant width from the barrier layer to the metal layer.

8. The electronic device of claim 1, wherein the seed layer consists of a single layer of copper.

9. The electronic device of claim 1, wherein the barrier layer comprises titanium, titanium-nitride, titanium-tungsten, tantalum, and/or tantalum-nitride.

10. The electronic device of claim 1, wherein the barrier layer consists of a layer made of titanium, titanium-nitride, titanium-tungsten, tantalum, and/or tantalum-nitride.

11. A method of manufacturing an electronic device, the method comprising:
providing an aluminum pad on a semiconductor substrate of the electronic device; and
forming a stack on the aluminum pad, the forming comprising:
depositing a barrier layer directly on the aluminum pad;
depositing a seed layer directly on the barrier layer, the seed layer comprising copper and having a thickness less than 800 nanometers (nm); and
depositing a metal layer directly on the seed layer, the metal layer comprising nickel and palladium.

12. The method of claim 11, wherein depositing the metal layer is performed via electroless deposition.

13. The method of claim 11, wherein depositing the barrier layer and the seed layer are performed via physical vapor deposition.

14. The method of claim 11, wherein depositing the metal layer directly on the seed layer comprises depositing a first metal sub-layer comprising nickel directly on the seed layer and depositing a second metal sub-layer comprising palladium directly on the first metal sub-layer.

15. The method of claim 14, wherein the first metal sub-layer substantially entirely covers a top surface of the seed layer.

16. The method of claim 11, wherein the seed layer is deposited with a thickness of 250-600 nm. 17 The method of claim 11, wherein the metal layer is deposited with a thickness greater than 500 nm.

18. The method of claim 11, wherein a sectional view of the seed layer has a substantially constant width from the barrier layer to the metal layer.

19. The method of claim 11, wherein the seed layer is deposited as a single layer of copper.

20. The method of claim 11, wherein the barrier layer is deposited as a single layer of titanium, titanium-nitride, titanium-tungsten, tantalum, and/or tantalum-nitride.
